(19) United States
(12) Patent Application Publication
(10) Pub. No.: US 2012/0132804 A1
(43) Pub. Date: May 31, 2012

(54) THERMAL IMAGE SENSOR WITH CHALCOGENIDE MATERIAL AND METHOD OF FABRICATING THE SAME

(76) Inventors: Tae-yon Lee, Seoul (KR); Dong-seok Suh, Hwaseong-si (KR); Yoon-dong Park, Yongin-si (KR)

(21) Appl. No.: 13/222,522

(22) Filed: Aug. 31, 2011

(30) Foreign Application Priority Data
Nov. 30, 2010 (KR) 10-2010-0120611

(51) Int. Cl. H01L 31/0248; H01L 31/0256; H01L 31/09; H01L 31/18

(52) U.S. Cl. 250/330; 438/54; 257/467; 257/E31.093

(57) ABSTRACT

A thermal image sensor including a chalcogenide material, and a method of fabricating the thermal image sensor are provided. The thermal image sensor includes a first metal layer formed on a substrate; a cavity exiting the first metal layer adapted for absorbing infrared rays; a bolometer resistor formed on the cavity and including a chalcogenide material; and a second metal layer formed on the bolometer resistor. The thermal image sensor includes a first metal layer formed on a substrate; an insulating layer formed on the first metal layer; a bolometer resistor formed on the insulating layer, including a chalcogenide material and having a thickness corresponding to ¼ of an infrared wavelength (λ); the thermal image sensor further includes a second metal layer formed on the bolometer resistor.

### CROSS-REFERENCE TO RELATED APPLICATIONS

This application claims the benefit of Korean Patent Application No. 10-2010-0120611, filed on Nov. 30, 2010, in the Korean Intellectual Property Office, the disclosure of which is incorporated by reference herein in its entirety.

### BACKGROUND

The inventive concept relates to a thermal image sensor, and more particularly, to an infrared sensor using a chalcogenide material as a bolometer resistor, a method of fabricating the infrared sensor, and a camera system using the infrared sensor.

In general, an infrared ray is a kind of electromagnetic wave, and has a wavelength that is longer than that of a visible ray and shorter than that of radio waves and microwaves. All organisms in the natural world, including human, emit infrared rays. Since Wavelengths of infrared rays emitted from the organisms differ according to temperatures of the organisms, image data may be detected using this property. An infrared sensor detects infrared rays by detecting a thermal change of infrared rays and converting the thermal change into an electrical signal.

### SUMMARY

In one embodiment, the inventive concept provides a thermal image sensor using a chalcogenide material having high temperature resistance properties and high infrared absorbance.

in another embodiment, the inventive concept also provides a method of fabricating the thermal image sensor.

In still another embodiment the inventive concept also provides a camera system using the thermal image sensor.

According to another embodiment of the inventive concept, there is provided a thermal image sensor including a first metal layer formed on a substrate; a cavity exiting on the first metal layer and resonance-absorbing infrared rays; a bolometer resistor formed on the cavity and including a chalcogenide material; and a second metal layer formed on the bolometer resistor.

In one embodiment, the chalcogenide material can include an AₐB_{b}S_{1-a-b}, an AₐB_{b}Te_{1-a-b} or an AₐB_{b} Se_{1-a-b} compound semiconductor, wherein an atom A is an atom selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni), or a combination of two or more thereof, and atom B is an atom selected from antimony (Sb), bismuth (Bi), arsenic (As), or phosphorus (P), or a combination of two or more thereof, and wherein the composition ratio of the chalcogenide material satisfies the requirements that a is in the range 0<a<1 and b is in the range 0<b<1.

In one embodiment, the cavity can be formed to have a vacuum space with a height of ¼ of an infrared wavelength (λ).

In another embodiment, each of the first and second metal layers includes one or more of the following: gold (Au), aluminum (Al), chrome (Cr), nickel (Ni), tungsten (W), titanium (Ti), tantalum (Ta), titanium tungsten (TiW), nickel chrome (NiCr), aluminum nitride (AlNₓ), titanium nitride (TiNₓ), titanium aluminum nitride (TiAlₓN_{y}), tantalum nitride (TaNₓ), tungsten silicide (WSiₓ), titanium silicide (TiSiₓ), cobalt silicide (CoSiₓ), wherein x and y are independent integers.

In another embodiment, the thermal image sensor further includes a cleavage portion formed in the second metal layer so as to provide a gap across a portion of the second metal layer. In one embodiment, the gap is across a central portion of the second metal layer.

In another embodiment of the inventive concept, a thermal image sensor is provided that includes a first metal layer formed on a substrate; an insulating layer formed on the first metal layer; a bolometer resistor formed on the insulating layer and wherein the bolometer resistor includes a chalcogenide material; and a second meal layer is formed on the bolometer resistor.

In another embodiment, the insulating layer includes a silicon oxide layer, a silicon nitride layer, a titanium oxide layer, an aluminum oxide layer, or a combination of any combination of the foregoing.

In another embodiment, the bolometer resistor can be formed to have a thickness corresponding to ¼ of an infrared wavelength (λ).

In certain embodiments the thermal image sensor further includes at least one gap formed in the second metal layer.

According to another embodiment of the inventive concept, a method of fabricating a thermal image sensor is provided, the method includes forming a first metal layer on a substrate; forming a sacrificial layer on the first meal layer; forming a resistance layer formed on the sacrificial layer by using a chalcogenide material; forming a second metal layer on the resistance layer; etching the second metal layer, the resistance layer and the sacrificial layer so as to form a bolometer; and removing the sacrificial layer so as to form a cavity suitable for absorbing infrared rays.

In another embodiment of the inventive concept, a method of fabricating a thermal image sensor is provided, the method includes forming a first metal layer on a substrate; forming an insulating layer on the first meal layer; forming a resistance layer on the insulting layer by using a chalcogenide material; forming a second metal layer on the resistance layer; and etching the second metal layer, the resistance layer and the sacrificial layer so as to form a bolometer.

The insulating layer can be formed to a thickness corresponding to 1/10 of an infrared wavelength (λ). In addition, the insulating layer can include a silicon oxide layer, a silicon nitride layer, a titanium oxide layer, an aluminum oxide layer, or a combination thereof, wherein the insulating layer has low thermal conductivity.

According to another embodiment of the inventive concept, a camera system including a thermal image sensor and a processor for controlling the thermal image sensor is provided, wherein the thermal image sensor includes a first metal layer formed on a substrate; a cavity exiting the first metal layer and resonance-absorbing infrared rays, i.e the cavity having a thickness suitable for absorbing infrared rays, the suitable thickness can be any thickness that causes significant absorption of infrared rays, such as for instance, but without limitation, one-quarter of a wavelength of the infrared light to be detected; a bolometer resistor is formed on the cavity and includes a chalcogenide material; and a second metal layer is formed on the bolometer resistor.

According to another embodiment of the inventive concept, a camera system including a thermal image sensor and a processor for controlling the thermal image sensor is provided, wherein the thermal image sensor includes a first metal layer formed on a substrate; an insulating layer is formed on the first metal layer, and wherein the first metal layer has a low thermal conductivity; and a bolometer resistor is formed on the insulating layer, wherein the bolometer resistor includes a chalcogenide material; and a second meal layer is formed on the bolometer resistor.

### BRIEF DESCRIPTION OF THE DRAWINGS

Exemplary embodiments of the inventive concept will be more clearly understood from the following detailed description taken in conjunction with the accompanying drawings in which:

FIG. 1 is an exploded view of a thermal image sensor according to an embodiment of the inventive concept;

FIG. 2 is a plan view of a bolometer array of FIG. 1, according to an embodiment of the inventive concept.

FIG. 3 is a perspective view of a single bolometer pixel in the bolometer array of FIG. 1, according to an embodiment of the inventive concept;

FIG. 4 is a cross-sectional view of the bolometer taken along a line A-A′ of FIG. 3, according to an embodiment of the inventive concept.

FIG. 5 is a diagram for describing a read-out integrated circuit (ROIC) formed on a substrate, according to an embodiment of the inventive concept;

FIGS. 6A through 6F are cross-sectional views for describing a method of fabricating the bolometer of FIG. 3, according to an embodiment of the inventive concept;

FIG. 7 is a perspective view of a bolometer according to another embodiment of the inventive concept;

FIG. 8 is a cross-sectional view of the bolometer taken along a line B-B′ of FIG. 7, according to another embodiment of the inventive concept;

FIG. 9 is a perspective view of a bolometer, according to another embodiment of the inventive concept;

FIG. 10 is a cross-sectional view of the bolometer taken along a line C-C′ of FIG. 9, according to another embodiment of the inventive concept

FIGS. 11A through 11E are cross-sectional views for describing a method of fabricating the bolometer of FIG. 9, according to another embodiment of the inventive concept;

FIG. 12 is a perspective view of a bolometer according to another embodiment of the inventive concept;

FIG. 13 is a cross-sectional view of the bolometer taken along a line D-D′ of FIG. 12, according to another embodiment of the inventive concept;

FIGS. 14 and 15 are graphs for describing properties of a chalcogenide material used as a bolometer resistor, according to one or more embodiments of the inventive concept;

FIG. 16 is a circuit diagram of an infrared sensor using a bolometer according to one or more embodiments of the inventive concept;

FIG. 17 is a block diagram of an image sensor using a bolometer according to one or more embodiment of the inventive concept;

FIG. 18 is a block diagram of a camera system using the infrared sensor of FIG. 16 or the image sensor of FIG. 17, according to an embodiment of the inventive concept; and

FIG. 19 is a block diagram of a computer system including the camera system of FIG. 18, according to an embodiment of the inventive concept.

### DETAILED DESCRIPTION

The inventive concept will now be described more fully with reference to the accompanying drawings, in which exemplary embodiments of the inventive concept are shown. The inventive concept may, however, be embodied in many different forms and should not be construed as being limited to the embodiments set forth herein; rather, these embodiments are provided so that this disclosure will be thorough and complete, and will fully convey the concept of the inventive concept to those of ordinary skill in the art. In the drawings, the thicknesses of layers and regions are exaggerated for clarity.

The terminology used herein is for the purpose of describing particular embodiments only and is not intended to be limiting of the inventive concept. As used herein, the singular forms “a,” “an” and “the” are intended to include the plural forms as well, unless the context clearly indicates otherwise. It will be further understood that the terms “comprises” and/or “comprising” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Infrared sensors may be largely classified into cooling-type infrared sensors for obtaining electrical signals generated by a reaction between photon in infrared rays and an electrons in a material, and noncooling-type infrared sensors for detecting a temperature change generated when infrared rays are absorbed into a material, according to performance properties. A cooling-type infrared sensor is mainly formed of semiconductor materials, and has low noise and fast response properties, but operates at a liquid nitrogen temperature (−193° C.). On the other hand, materials used for forming a noncooling-type infrared sensor have somewhat lower than semiconductor materials, but operates at room temperature.

The noncooling-type infrared sensors operate at room temperature of about 300° K by using a principle of detecting a property change of a material according to a temperature of the material. From among the noncooling-type infrared sensors, an infrared sensor of detecting a resistance change of a material is referred to as a bolometer.

A bolometer-type infrared sensor includes a material that absorbs infrared rays and converts the absorbed infrared rays into heat, a unit for thermally separating a bolometer structure so that a temperature of the bolometer structure may be increased, a unit for converting a temperature change into a resistance change, and a unit for reading the resistance change.

To obtain an infrared image by using the bolometer-type infrared sensor, the bolometer-type infrared sensor needs to be fabricated in a two-dimensional array shape, and needs to be fabricated by a monolithic integration process of forming a signal processing circuit and a switch right below a sensor structure, that is, on the same substrate in order to read an array-type sensor signal. The bolometer-type infrared sensor fabricated in an array type may be installed in a package in which a vacuum can be formed, and may obtain an infrared image by processing signals.

The performance of the non-cooling type bolometer infrared sensor is determined according to the property of an infrared ray inductor, a structure for accumulating the material, a method of fabricating the structure, a technology for designing a unit for supporting the structure so as not to be mechanically weak and to be sufficiently thermally-separated, a read-out circuit for processing output signals and performing various corrections and the performance of a package for maintaining a vacuum.

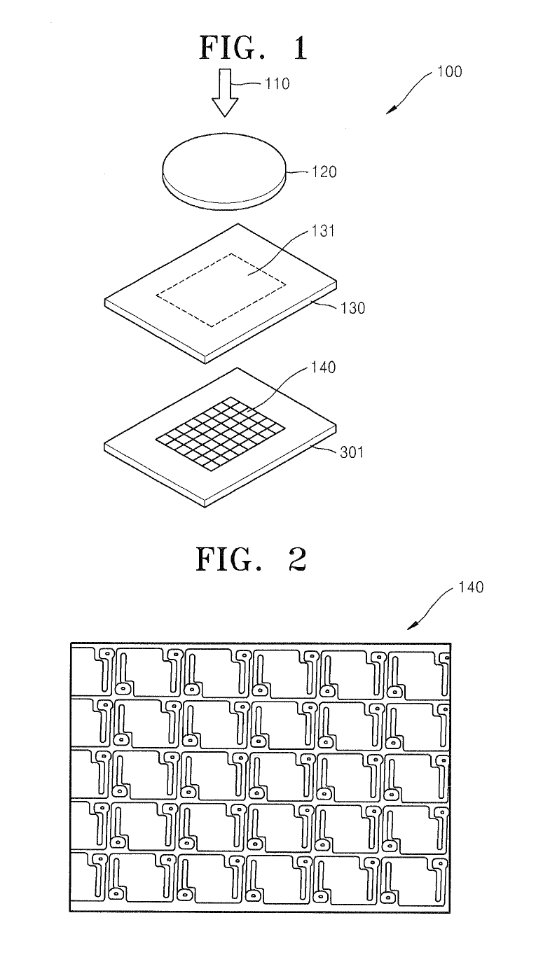

FIG. 1 is an exploded view of a thermal image sensor 100 according to an embodiment of the inventive concept. The thermal image sensor 100 indicates any infrared sensor for absorbing infrared rays emitted from an object and displaying an image. Referring to FIG. 1, an arrow 110 indicates emitted infrared rays transmitted through an infrared image lens 120. A cover of a package 130 includes a window region 131 through which waves of the infrared rays 110 are transmitted. The package 130 is formed in a sealing package form in order to improve sensibility and isolation of internal pixels and to reduce contamination and reduction in performance. A bolometer array 140 in the package 130 is formed on a substrate 301 formed of silicon or a similar material thereof having electrical micromachining properties. FIG. 2 is a plan view of the bolometer array 140 of FIG. 1, according to an embodiment of the inventive concept.

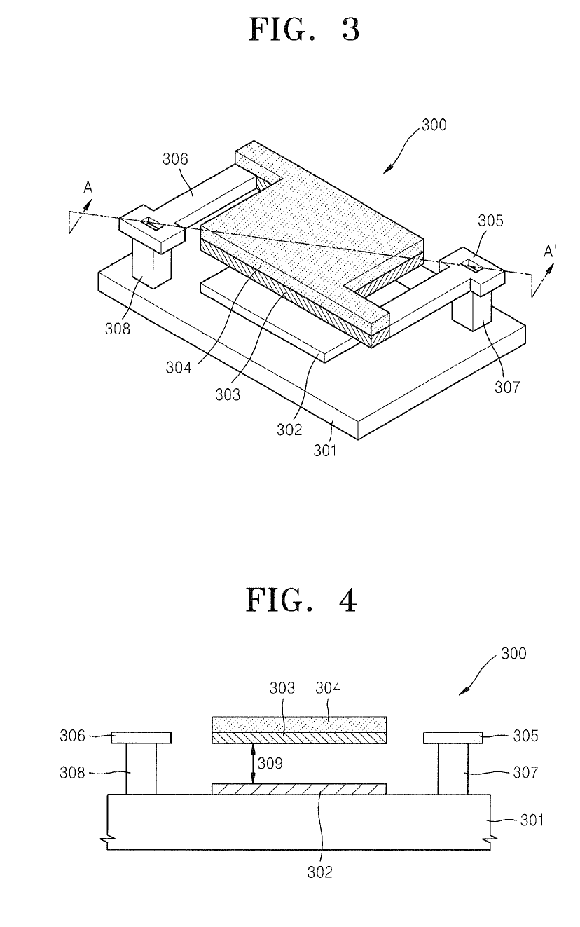

FIG. 3 is a perspective view of a single bolometer pixel (hereinafter, referred to as a “bolometer”) in the bolometer array 140 of FIG. 1, according to an embodiment of the inventive concept. FIG. 4 is a cross-sectional view of the bolometer taken along a line A-A′ of FIG. 3, according to an embodiment of the inventive concept. Referring to FIGS. 3 and 4, the bolometer 300 includes a first metal layer 302 formed on the substrate 301, a resistor 303 spaced apart from the first metal layer 302 by conductive supporters 307 and 308 formed on the substrate 301, a second metal layer 304 formed on the resistor 303, and connectors 305 and 306 for connecting resistor 303, and the supporters 307 and 308 to each other.

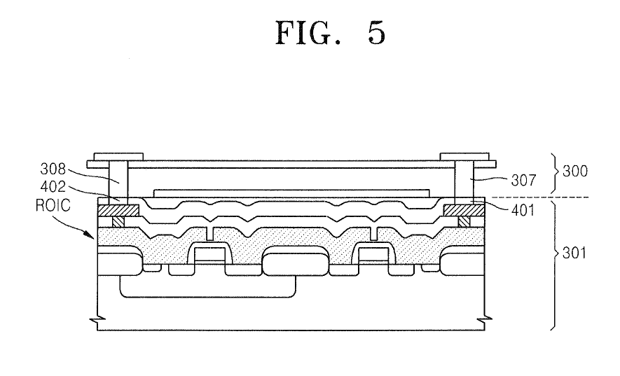

A read-out integrated circuit (ROIC) receiving signals from the bolometer 300 is formed on the substrate 301. The ROIC may be embodied as a complementary metal oxide semiconductor (CMOS) manufactured by using a method of manufacturing a semiconductor integrated circuit (IC), as shown in FIG. 5. Electrode pads 401 and 402 for connecting the ROIC and the supporters 307 and 308 of the bolometer 300 to each other are formed on the substrate 301. A protection layer for planarizing the substrate 301 and protecting the ROTC may be formed on the substrate 301 except for portions where the electrode pads 401 and 402 are formed, and may include a silicon oxide (SiO₂) layer, a silicon nitride (Si₃N₄) layer, or the like.

The first metal layer 302 functions as an infrared reflective layer for reflecting infrared rays. The first metal layer 302 may be formed of gold (Au), aluminum (Al), chromium (Cr), nickel (Ni), titanium (Ti) or an alloy of any two or more thereof.

A cavity 309 is formed between the first metal layer 302 and the resistor 303 in order to absorbance of infrared rays. The cavity 309 is formed to have a height of ¼ of an infrared wavelength (λ) to be absorbed so as to generate resonance. The infrared wavelength (λ) may be from 8 to 14 um. The cavity 309 may have a height of 2 to 3.5 um, a vacuum may be formed in the cavity, and the cavity 309 may be filled with a dielectric material having low thermal conductivity. The dielectric material may include SiO₂, Si₃N₄, TiO, AlO, or combinations thereof.

The resistor 303 is formed of a material having resistance that varies according to a temperature of the material. Image data may be obtained by detecting a change in the resistance. The resistor 303 is formed of a chalcogenide material including a chalcogenide atom of a group VI of the periodic table. The resistor 303 includes a germanium antimony telluride (Ge₂Sb₂Te₅; hereinafter, referred as “GST”) material including the chalcogenide material.

The GST material has an excellent temperature coefficient of resistance (TCR) as properties for converting a temperature change into a resistance change. For example, a TCR of a vanadium oxide (VOₓ) material is about 2%, whereas a TCR of the GST material is about 4%. Thermal conductivity of the VOₓ material is about 5 W/mK, whereas thermal conductivity of the GST material is about 0.6 W/mK. In addition, the GST material has high infrared absorbance, and has high electrical conductivity since resistivity of the GST material is from 0.1 to 1 Ωcm according to a crystalline state or an amorphous state. Examples of the chalcogenide include GaSb, InSb, InSe, Sb₂Te₅, GeTe, InSbTe, GaSeTe, SnSb₂Te₄, InSbGe, AgInSbTe, (GeSn)SbTe, GeSb(SbTe), and Te₈₁Ge₁₅Sb₂S₂.

The chalcogenide material may be variously configured by, as desired, substituting and combining S, Te and Se constituting a chalcogenide in the GST material. One atom selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni), or a combination thereof will be referred to as an atom ‘A’. In addition, any atom selected from antimony (Sb), bismuth (Bi), arsenic (As), or phosphorus (P), or a combination thereof will be referred to as an atom ‘B’. The chalcogenide material may include a AₐB_{b}S_{1-a-b}, AₐB_{b}Te_{1-a-b}, or AₐB_{b}Se_{1-a-b} compound semiconductor. An atom ratio of Aₐ, B_{b} and S_{1-a-b} satisfies 0<a<1 and 0<b<1. An atom ratio of Aₐ, B_{b} and Te_{1-a-b} satisfies 0<a<1 and 0<b<1, and an atom ratio of Aₐ, B_{b} and Se_{1-a-b} satisfies 0<a<1 and 0<b<1.

The second metal layer 304 may easily transmit incident infrared rays therethrough, and may easily reflect the infrared rays in the cavity 309. The second metal layer 304 can include at least one selected from the group consisting of Ti, Ni, Pt, and the like.

The first metal layer 302 and the resistor 303 are spaced apart from each other by the supporters 307 and 308 by as much as the cavity 309. The supporters 307 and 308 support the resistor 303 and the second metal layer 304. The supporters 307 and 308 may be formed of a conductive material such as Au, Al, Cr, Ni, Ti, or an alloy thereof.

The connectors 305 and 306 may electrically connect the resistor 303 and the supporters 307 and 308 to each other. The connectors 305 and 306 may include at least one material having low thermal conductivity and resistance, such as Ni, Ti, and TiN.

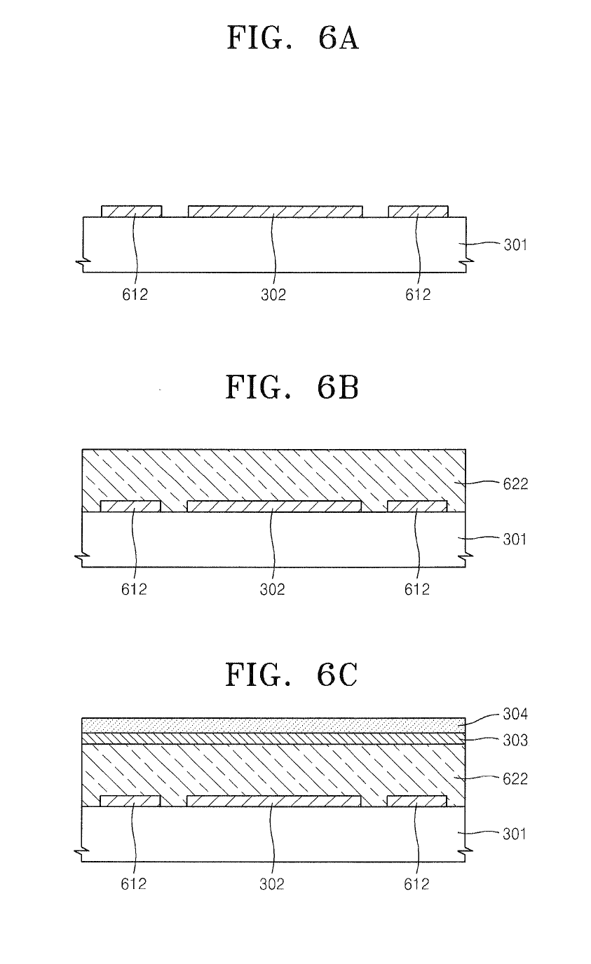

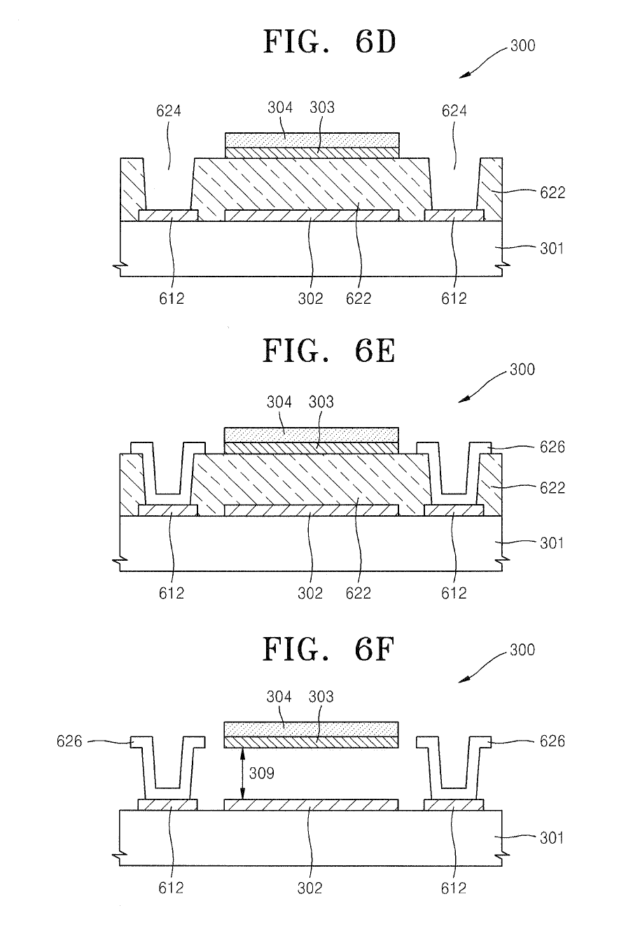

FIGS. 6A through 6F are cross-sectional views for describing a method of fabricating the bolometer 300 of FIG. 3, according to an embodiment of the inventive concept. The method of fabricating the bolometer 300 will be described with respect to the line A-A′ of FIG. 3.

Referring to FIG. 6A, the first metal layer 302, and metal pads 612 spaced apart from the first metal layer 302 by a predetermined interval are formed on a surface of the substrate 301 on which the ROIC is formed. The first metal layer 302 and the metal pad 612 may be formed of a material having excellent surface reflectivity and conductivity, and may be simultaneously formed by depositing the material by using an evaporation or sputtering apparatus.

The first metal layer 302 and the metal pad 612 may be formed of gold (Au), aluminum (Al), chrome (Cr), nickel (Ni), tungsten (W), titanium (Ti), tantalum (Ta), titanium tungsten (TiW), nickel chrome (NiCr), aluminum nitride (AlNₓ), titanium nitride (TiNₓ), titanium aluminum nitride (TiAlₓN_{y}), tantalum nitride (TaNₓ), tungsten silicide (WSiₓ), titanium silicide (TiSiₓ), cobalt silicide (CoSiₓ), or the like. In this case, x and y are independent integers. These materials may be used alone or in a combination of at least two of them. The metal pad 612 may be electrically connected to the electrode pads 401 and 402 (see FIG. 5) connected to the ROIC formed on the substrate 301.

Referring to FIG. 6B, a sacrificial layer 622 is formed on the substrate 301. The sacrificial layer 622 may be a layer to be removed in a subsequent process, and may be formed of a material with excellent abrasion-resistance and heat resistance, such as polyimide. The sacrificial layer 622 is formed by coating the material to a thickness corresponding to λ/4 by spin coating and then curing the resultant layer of desired thickness.

Referring to FIG. 6C, a resistance layer 303 and the second metal layer 304c are sequentially formed on the substrate 301 on which the sacrificial layer 622 is formed in FIG. 6B. The resistance layer 303 is formed of a chalcogenide material, for example, a GST material. Since it is easy to form a uniform thin film on a large area by using the chalcogenide material such as GST, it is easier to form a uniform thin film by using the chalcogenide material than using a VOₓ material. The resistance layer 303 may be formed on the sacrificial layer 622 by using various chemical and physical vapor deposition methods, for example, evaporation, sputter, chemical-vapor-deposition, and atomic layer deposition.

The second metal layer 304 may be formed of Au, Al, Cr, Ni, W, Ti, Ta, TiW, NiCr, AlNₓ, TiNₓ, TiAlₓN_{y}, TaNₓ, WSiₓ, TiSiₓ, CoSiₓ, or the like. In this case, and y are independent integers. These materials may be used alone or in a combination of at least two of them.

Referring to FIG. 6D, the second metal layer 304, the resistance layer 303 and the sacrificial layer 622 are sequentially etched to form holes 624 for exposing the metal pad 612 therethrough. The second metal layer 304 and the resistance layer 303 form the bolometer 300. Thus, the bolometer 300 is spaced apart from the first metal layer 302 by as much as λ/4. The etched resistance layer 303 is the same as the resistor 303 of FIG. 3. In FIG. 3, the resistor 303 has a rectangular shape. The term ‘rectangular shape’ may include any polygonal shape such as a square shape, a parallelogram, trapezoid, and hexagon.

Referring to FIG. 6E, an electrode 626 is formed to cover the metal pad 612. The electrode 626 may be formed of Au, Al, Cr, Ni, W, Ti, Ta, TiW, NiCr, AlNₓ, TiNₓ, TiAlₓN_{y}, TaNₓ, WSiₓ, TiSiₓ, CoSiₓ, or the like. In each case, x and y are independent integers. These materials may be used alone or in a combination of at least two of them. As shown in FIG. 3, electrodes 626 are formed by the connectors 305 and 306 and the supporters 307 and 308, which are connected to the resistance layer 303 of a bolometer 600.

Referring to the embodiment of FIG. 6F, the sacrificial layer 622 is removed using a plasma ashing method using a mixture gate including oxygen (O₂). Thus, the cavity 309 in which a vacuum is formed is created between the first metal layer 302 and the bolometer 300 so as to correspond to a thickness of the sacrificial layer 622.

Although not illustrated, in order to protect the bolometer 300 from physical distortion such as scratch, an additional protection layer may be formed on the bolometer 300. The protection layer may be formed of oxide such as silicon oxide, a nitride such as silicon nitride, or oxynitride such as silicon oxynitride. The protection layer may be formed using undoped silicate glass (USG), boro-phosphor silicate glass (BPSG), phosphor silicate glass (PSG), flowable oxide (FOX), tetraethyl ortho silicate (TEOS), plasma enhanced-tetraethyl ortho silicate (PE-TEOS), spin on glass (SOG), tonen silazene (TOSZ), fluoride silicate glass (FSG), or the like.

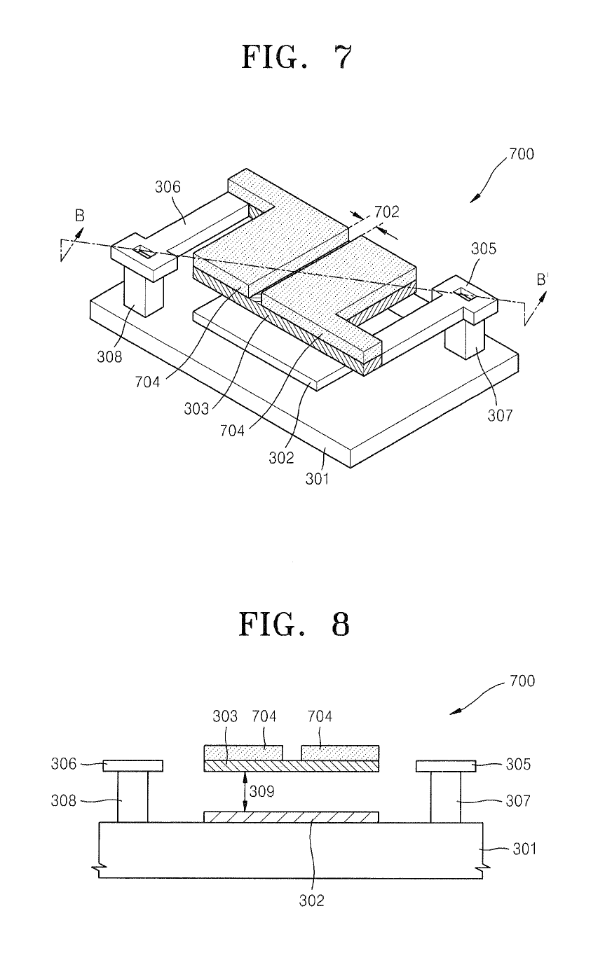

FIG. 7 is a perspective view of a bolometer 700 according to another embodiment of the inventive concept. FIG. 8 is a cross-sectional view of the bolometer taken along a line B-B′ of FIG. 7, according to another embodiment of the inventive concept. Referring to FIGS. 7 and 8, the bolometer 700 is different from the bolometer 300 of FIG. 3 in that a cleavage portion 702 is formed in the middle of a second metal layer 704.

Due to the structural characteristics of a bolometer spaced apart from a substrate, an upper portion of the bolometer may thermally expand during a thermal process included in a method of fabricating an infrared sensor. In addition, a stress may be generated in the upper portion of the bolometer by a thermal stress during use of the bolometer. Thus, the upper portion of the bolometer may be bent or deformed. According to the present embodiment, the stress may be removed by forming the cleavage portion to create a gap, 702 in the middle of the second metal layer 704.

The bolometer 700 of the embodiment depicted in FIG. 2 may be fabricated by using the same method as the above-described method described with reference to FIGS. 6A through 6F. However, the second metal layer 704 in the bolometer 700 can be divided, for instance, the second metal layer 304 in FIG. 6D can be etched so that the cleavage portion creates a gap; similarly, gap 702 may be formed in the middle of the second metal layer 704 as shown in the pattern of the second metal layer 704 of FIGS. 7 and 8.

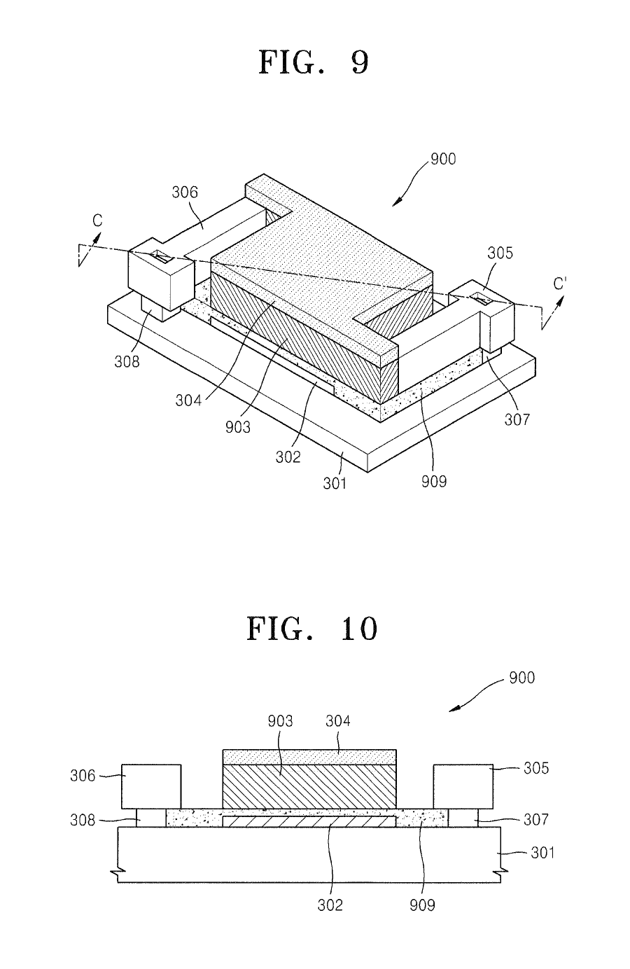

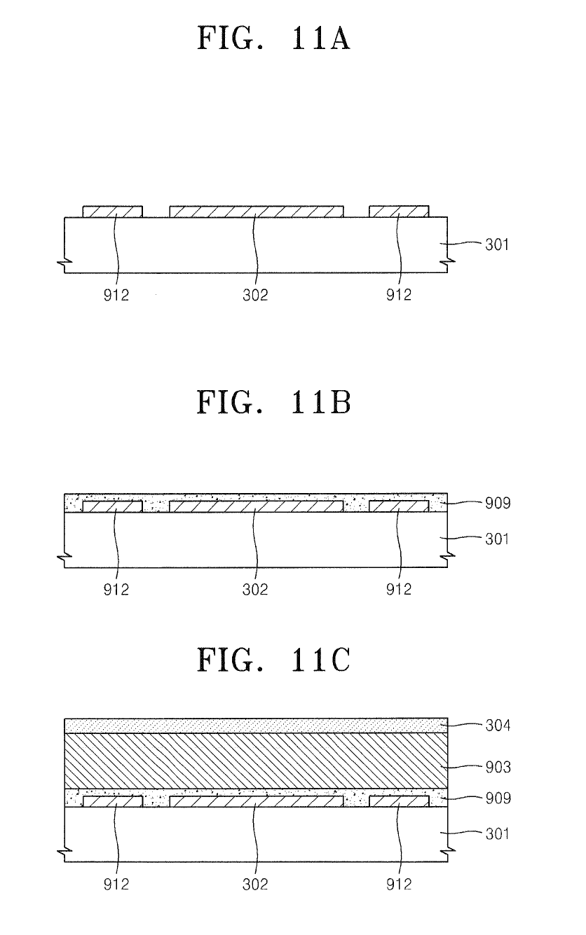

FIG. 9 is a perspective view of a bolometer 900, according to another embodiment of the inventive concept. FIG. 10 is a cross-sectional view of the bolometer 900 taken along a line C-C′ of FIG. 9, according to another embodiment of the inventive concept. Referring to FIGS. 9 and 10, the bolometer 900 is different from the bolometer 300 of FIG. 3 in that an insulating layer 909 is formed between the first metal layer 302 and a resistor 903, and the resistor 903 is formed to thick so as to almost fill the cavity 309 of FIG. 3. The insulating layer 909 is formed of a dielectric material having low thermal conductivity, such as SiO₂, Si₃N₄, TiO, AlO, or a combination of at least two of them. Since the resistor 903 is formed to be of a thickness to resist deformation, an upper portion of the bolometer 900 may be prevented from being distorted.

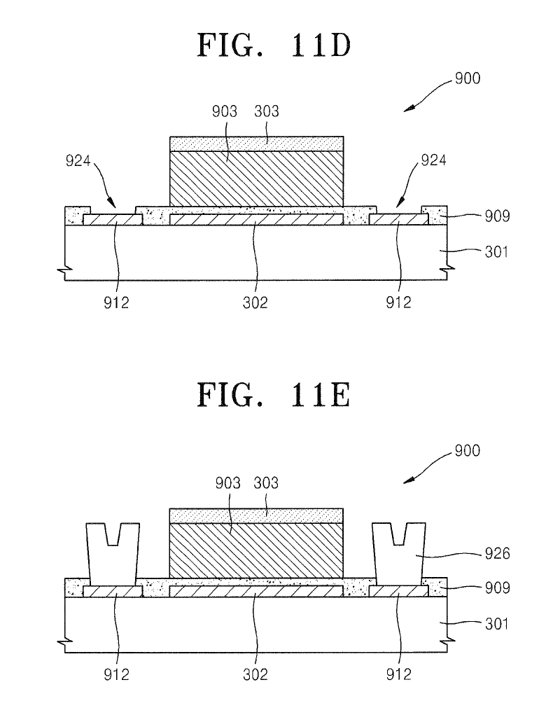

FIGS. 11A through 11E are cross-sectional views for describing a method of fabricating the bolometer 900 of FIG. 9, according to another embodiment of the inventive concept. The method of fabricating the bolometer 900 will be described with respect to the line C-C′ of FIG. 9.

Referring to FIG. 11A, the first metal layer 302, and metal pads 912 spaced apart from the first metal layer 302 by a predetermined interval are formed on a surface of the substrate 301 on which the ROIC is formed. The first metal layer 302 and the metal pad 912 may be formed of a material having excellent surface reflectivity and conductivity, and may be simultaneously formed by depositing the material. The first metal layer 302 and the metal pad 912 may be formed of Au, Al, Cr, Ni, W, Ti, Ta, TiW, NiCr, AlNₓ, TiNₓ, TiAlₓN_{y}, TaNₓ, WSiₓ, TiSiₓ, CoSiₓ, or the like. In this case, x and y are independent integers. These materials may be used alone or in a combination of two or more of them.

Referring to FIG. 11B, the insulating layer 909 is formed on the substrate 301. The insulating layer 909 may be formed to have a small thickness corresponding to λ/10, where λ is the infrared wavelength to be detected. The insulating layer 909 may be formed of a material having low thermal conductivity, such as SiO₂, Si₃N₄, TiO, AlO, or a combination of at least two of them.

Referring to FIG. 11C, a resistance layer 903 and the second metal layer 304 are sequentially formed on the substrate 301 on which the insulating layer 909 of FIG. 11B is formed. The resistance layer 903 includes an amorphous germanium antimony telluride (Ge₂Sb₂Te₅) material including the chalcogenide material.

The resistance layer 903 may be formed on the insulating layer 909 by using a PECVD or PEALD method using plasma. The resistance layer 903 is formed by a RF magnetron sputter apparatus. In addition to the RF magnetron sputter apparatus, a thermal deposition apparatus may be used. The resistance layer 903 may adjust crystallization of a GST material layer during deposition by appropriately adjusting a power of plasma or a ratio of reaction gases. Examples of the reaction gases may be a reducing gas, an inert gas, or a combination thereof, and a ratio between the reaction gases may be adjusted. The reaction gases may be H₂, NH₃, He, Ar, Xe or a combination of two or more of them. The resistance layer 903 is formed to have a thickness corresponding to λ/4.

The second metal layer 304 may be formed of Au, Al, Cr, Ni, W, Ti, Ta, TiW, NiCr, AlNₓ, TiNₓ, TiAlₓN_{y}, TaNₓ, WSiₓ, TiSiₓ, CoSiₓ, or the like. In this case, x and y are independent integers. These materials may be used alone or in a combination of two or more of them.

Referring to FIG. 11D, the second metal layer 304, the resistance layer 903 and the insulating layer 909 are sequentially etched to form holes 924 for exposing the metal pads 912. The second metal layer 304 and the resistance layer 903 form the bolometer 900. The etched resistance layer 903 is the same as the resistor 903 of FIG. 9. In FIG. 9, the resistor 903 has a rectangular shape. The term ‘rectangular shape’ may include any polygonal shape such as a square shape, a parallelogram, trapezoid, and hexagon.

Referring to FIG. 11E, an electrode 926 is formed to cover the metal pad 912. The electrode 926 may include a single layer or a composite layer that are formed of any one selected from the group consisting of Au, Al, Cr, Ni, Ti, TiW or NiCr. The electrode 926 includes the connectors 305 and 306 connected to the resistance layer 903 of the bolometer 900, and the supporters 307 and 308, as shown in FIG. 9.

Although not illustrated, an additional protection layer may be formed on the bolometer 300 to protect the bolometer 300 from any physical distortion such as a scratch. The protection layer may be formed of oxide such as silicon oxide, a nitride such as silicon nitride, or oxynitride such as silicon oxynitride. The protection layer may be formed using undoped silicate glass (USG), boro-phosphor silicate glass (BPSG), phosphor silicate glass (PSG), flowable oxide (FOX), tetraethyl ortho silicate (TEOS), plasma enhanced-tetraethyl ortho silicate (PE-TEOS), spin on glass (SOG), tonen silazene (TOSZ), fluoride silicate glass (FSG), or the like.

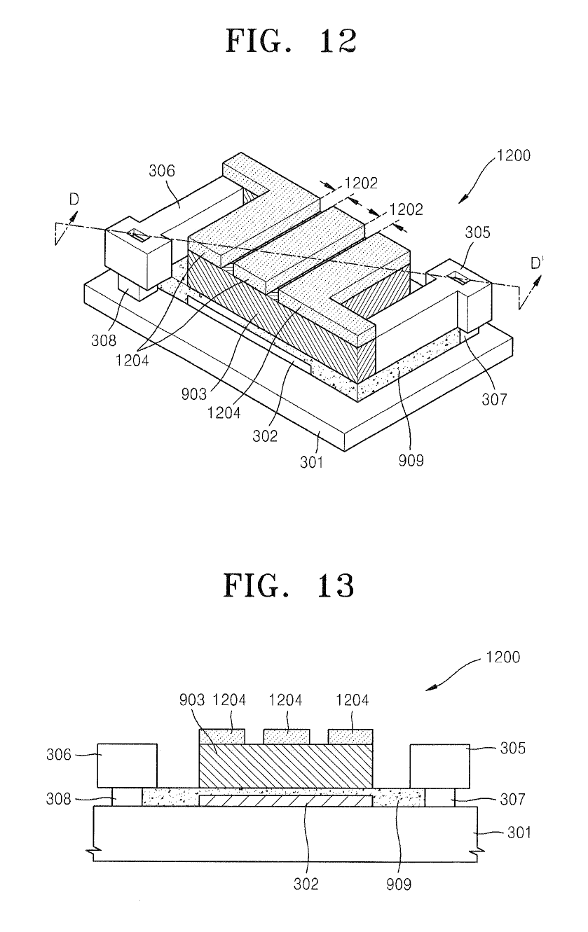

FIG. 12 is a perspective view of a bolometer 1200 according to another embodiment of the inventive concept. FIG. 13 is a cross-sectional view of the bolometer 1200 taken along a line D-D′ of FIG. 12, according to another embodiment of the inventive concept. Referring to FIGS. 12 and 13, the bolometer 1200 is different from the bolometer 900 of FIG. 9 in the at least one cleavage portion 1202 is formed in a second metal layer 1204. The at least one cleavage portion 1202 is formed in the second metal layer 1204 so as to prevent an upper portion of the bolometer 1200 from being bend or deformed.

The bolometer 1200 of FIG. 12 may be fabricated by using the same method as the above-described method described with reference to FIGS. 11A through 11F. However, in order to cut the second metal layer 1204 in the bolometer 1200, the second metal layer 304 in FIG. 11D can be etched so that the at least one cleavage portion 1202 is formed in the second metal layer 1204 like a pattern of the second metal layer 1204 of FIG. 13.

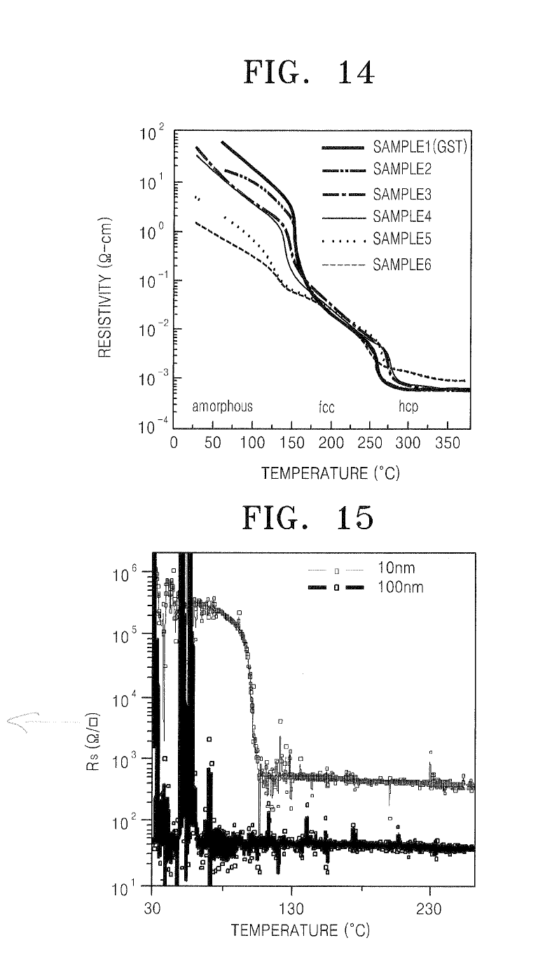

FIGS. 14 and 15 are graphs for describing properties of a chacogenidechalcogenide material used as a bolometer resistor, according to one or more embodiments of the inventive concept. FIG. 14 shows resistance properties of, as the chalcogenide material, an alloy (hereinafter, referred to as a “GeSbTe material”) of germanium (Ge), antimony (Sb) and tellurium (Te) and an alloy (hereinafter, referred to as a “GeBiTe material”) of Ge, bismuth (Bi) and Te, according to a temperature. A pure GeSbTe material is changed from an amorphous state to a crystalline state, and resistance properties of the pure GeSbTe material is linearly changed, as a temperature increases. When the GeSbTe material is deposited, the resistance properties are linearly changed based on a composition ratio of the GeBiTe material, for example, 13.1%, 35.1%, 38.4%, 56.6% and 61.2%, according to a temperature. That is, when the GeSbTe material is deposited, the resistance properties can be adjusted according to a composition ratio of the GeBiTe material.

FIG. 15 shows sheet resistance properties of a Sb thin film, according to a temperature. When a thickness of the Sb thin film is 10 nm, the sheet resistance properties are linearly changed compared to a case where a thickness of the Sb thin film is 100 nm. That is, the thinner the Sb thin film, the better a TCR.

Thus, since the chalcogenide material used as the bolometer resistor has an excellent TCR for changing a temperature change to a resistance change, and has linear resistance properties according to an amorphous state or a crystalline state, the chalcogenide material has excellent conductivity. Thus, the chalcogenide material has an excellent infrared response.

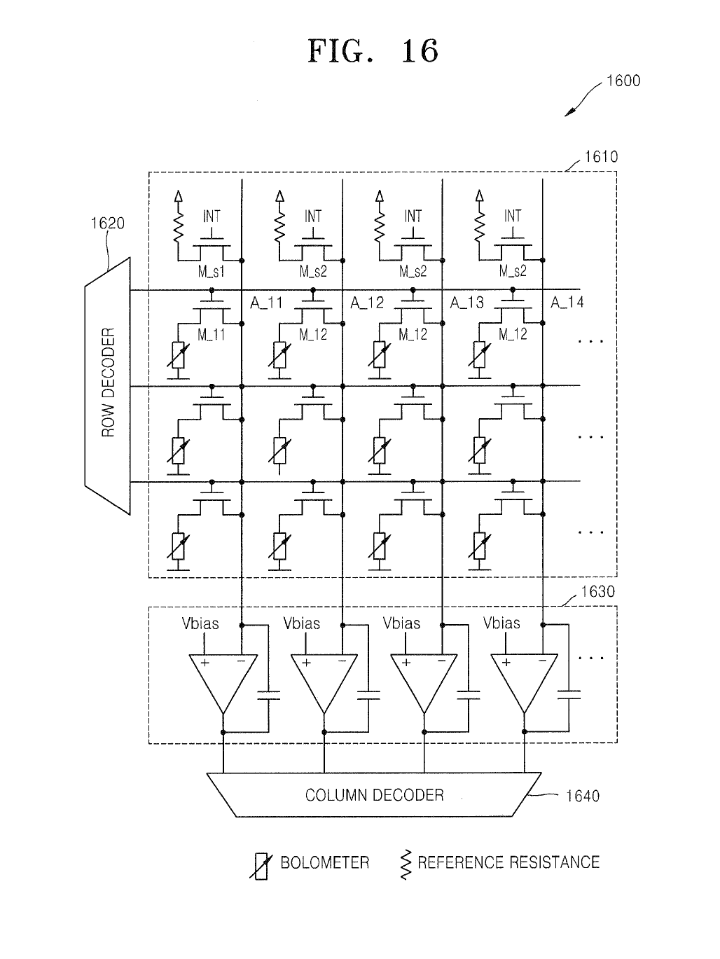

FIG. 16 is a circuit diagram of an infrared sensor 1700 using a bolometer according to one or more embodiments of the inventive concept. Referring to FIG. 16, the infrared sensor 1700 includes a bolometer array 1610, a row decoder 1620, an infrared signal detection circuit 1630, and a column decoder 1640. The bolometer array 1610 is the same as the bolometer array of FIG. 1. In the bolometer array 1610, the bolometer according to one or more embodiments of the inventive concept is indicated by a variable resistance. For convenience of description, 4*4 bolometer pixels are arranged in the bolometer array 1610, but are not limited thereto. In the bolometer array 1610, the bolometer with a resistance value changed according to incident infrared rays is disposed two-dimensionally, and includes a reference resistance having a constant resistance value regardless of incident infrared rays.

The row decoder 1620 controls an operation of the bolometer disposed in the bolometer array 1610 in units of horizontal lines. By signals output from the row decoder 1620, first column switches M_11, M_12, M_13 and M_14 are turned on. In this case, switches M_s1, M_s2, M_s3 and M_s4 are turned on by a control signal INT. The control signal INT is activated while signals detected by the bolometer are integrated. The reference resistance is connected to the bolometer with a resistance value changed according to incident infrared rays so that voltage levels of nodes A_11, A_12, A_13 and A_14 may be determined by a voltage drop between the resistance of the bolometer and the reference resistance.

The infrared signal detection circuit 1630 includes an integrator for amplifying a difference between the voltage levels of the nodes A_11, A_12, A_13 and A_14 and a bias voltage Vbias. The integrator includes an operational amplifier and a feedback capacitor. The integrator compares a voltage change based on the change in the resistance of the bolometer with the bias voltage Vbias, detects a difference between the voltage change and the bias voltage Vbias, and integrates the difference for a predetermined period of time to generate output signals. The column decoder 1640 finally outputs the signals integrated by each integrator for the predetermined period of time in units of vertical lines. The finally output signals are displayed by images.

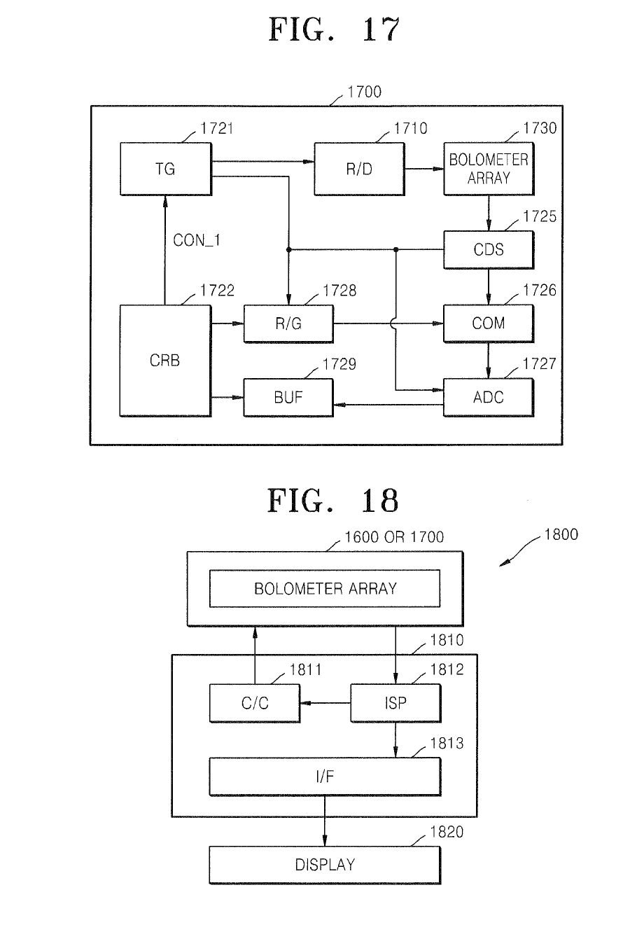

FIG. 17 is a block diagram of an image sensor 1700 using a bolometer according to one or more embodiment of the inventive concept. Referring to FIG. 17, the image sensor 1700 includes a timing signal generator 1721, a control register 1722, a row decoder 1710, a bolometer array 1730, a column decoder and a selection unit 1725, a comparer 1726, an analog-digital converter 1727, a lamp signal generator 1728, and a buffer 1729.

The timing signal generator 1721 generates a clock signal for controlling operations of the row decoder 1710, the lamp signal generator 1728, the column decoder and a selection unit 1725, and the analog-digital converter 1727, in response to an internal control signal CON_I received from the control register 1722. The control register 1722 generates the internal control signal CON_I in response to a control signal received from an external processor, and controls operations of the lamp signal generator 1728 and the buffer 1729.

The row decoder 1710, the bolometer array 1730, and the column decoder and a selection unit 1725 are the same as the row decoder 1620, the bolometer array 1610 and the column decoder 1640 of FIG. 16, respectively, and thus their description will be schematically described. The row decoder 1710 controls an operation of the bolometer disposed in the bolometer array 1730 in units of horizontal lines. In the bolometer array 1730, the bolometer with a resistance value changed according to incident infrared rays is disposed two-dimensionally. The column decoder and a selection unit 1725 outputs a detection signal that is obtained by integrating a resistance change of the bolometer in units of vertical lines.

The comparer 1726 compares a detection signal output from the column decoder and a selection unit 1725 in response to a lamp signal output from the lamp signal generator 1728 with a predetermined reference signal. The analog-digital converter 1727 converts a signal generated as a comparison result of the comparer 1726 to a digital signal so as to generate image data. The lamp signal generator 1728 generates the lamp signal according to an instruction of the control register 1722. The buffer 1729 stores or outputs the image data output from the analog-digital converter 1727 according to the instruction of the control register 1722.

The infrared sensor 1600 of FIG. 16 or the image sensor 1700 of FIG. 17 uses the chalcogenide material having excellent electrical conductivity due to a high TCR, high infrared absorbance and linear resistance properties, as a bolometer resistor. Thus, the infrared sensor 1600 or the image sensor 1700 improves infrared response. In addition, the infrared sensor 1600 or the image sensor 1700 includes at least one cleavage portion in a second metal layer on the bolometer resistor, thereby removing a stress generated during manufacturing processes or use of the bolometer. Thus, the infrared sensor 1600 or the image sensor 1700 improves product reliability.

The infrared sensor 1600 of FIG. 16 or the image sensor 1700 of FIG. 17 may be used in various application fields, for example, in cameras, camcorders, optical communication (both fibers and free spaces), laser detection and ranging (LADAR), infrared microscopes and infrared telescopes; the image sensor may also be used in medical imaging systems that provides images useful in interpreting medical information about existence or degree of diseases or prevents diseases by measuring, processing and analyzing a minute change in temperature of a surface of human without pain or adverse reactions in medical fields, such as infrared imaging systems, an environment monitoring system such as produce monitoring devices and sea contamination monitoring devices, temperature monitoring systems in a semiconductor processing line, building insulation and water-leakage ranging system, and electrical and electronic printed circuit board (PCB) circuit and component test systems.

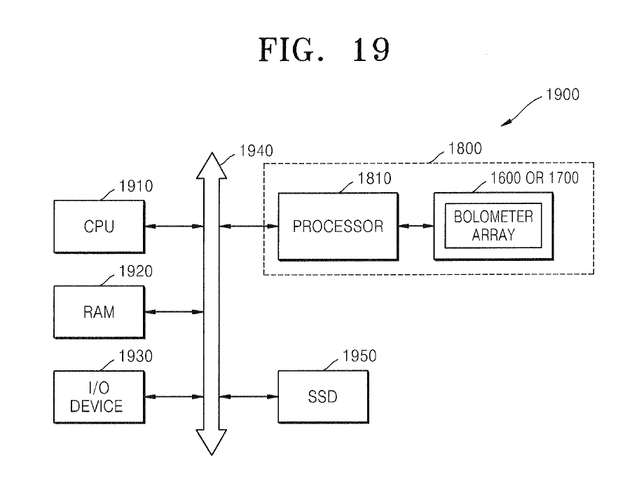

FIG. 18 is a block diagram of a camera system 1800 using the infrared sensor 1600 of FIG. 16 or the image sensor 1700 of FIG. 17, according to an embodiment of the inventive concept. Referring to FIG. 18, the camera system 1800 includes a processor 1810 that is coupled to the infrared sensor 1600 of FIG. 16 or the image sensor 1700 of FIG. 17. The cameral system 1800 may include an individual integrated circuit, or alternatively both the processor 1810 and the infrared sensor 1600 or the image sensor 1700 may be disposed on the integrated circuit. The processor 1810 may be a micro processor, an image processor, an application-specific integrated circuit (ASIC), or the like.

The processor 1810 includes a camera controller 1811, an image signal processor 1812, and an interface unit 1813. The camera controller 1811 outputs a control signal to the infrared sensor 1600 or the image sensor 1700. The image signal processor 1812 receives image data output from the infrared sensor 1600 or the image sensor 1700, and performs signal-processing on the image data. The interface unit 1813 transmits the data to a display 1820 so that the display 1820 may display the data.

FIG. 19 is a block diagram of a computer system 1900 including the camera system 1800 of FIG. 18, according to an embodiment of the inventive concept. Referring to FIG. 19, the computer system 1900 includes a central processing unit (CPU) 1910, a random access memory (RAM) 1920, an I/O device 1930, a memory system 1950, and the camera system 1800. The computer system 1900 is connected to the CPU 1910, the RAM 1920, the I/O device 1930, the memory system 1950, and the camera system 1800 through a system bus 1940. Data provided through the I/O device 1930 or the camera system 1800 or processed by the CPU 1910 is stored in the RAM 1920 or the memory system 1950. The memory system 1950 may include a memory card including a non-volatile memory device such as a NAND flash memory or a semiconductor disk device (SSD).

The camera system 1800 includes the processor 1810 coupled to the infrared sensor 1600 or the image sensor 1700. The infrared sensor 1600 or the image sensor 1700 uses the chalcogenide material as the bolometer resistor material, and includes at least one cleavage portion creating a gap in a second metal layer on the bolometer resistor, thereby removing a stress generated during manufacturing processes or use of the bolometer. Thus, the camera system 1800 has high infrared response and improved product reliability.

While the inventive concept has been particularly shown and described with reference to exemplary embodiments thereof, it will be understood that other variations in form and details may be made therein without departing from the spirit and scope of the following claims.

What is claimed is:

1. A thermal image sensor comprising:
a first metal layer formed on a substrate;
a cavity exiting the first metal layer adapted for absorbing infrared rays;
a bolometer resistor formed on the cavity and comprising a chalcogenide material; and
a second metal layer formed on the bolometer resistor.

2. The thermal image sensor of claim 1, wherein the chalcogenide material comprises a AₐB_{b}S_{1-a-b}, AₐB_{b}Te_{1-a-b} or AₐB_{b}Se_{1-a-b} compound semiconductor,
wherein A is an atom selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni), or a combination thereof,
B is an atom selected from the group consisting of antimony (Sb), bismuth (Bi), arsenic (As), or phosphorus (P), or a combination thereof, and
and having a composition of the chalcogenide material satisfying the formulae 0<a<1 and 0<b<1.

3. The thermal image sensor of claim 1, wherein the cavity is formed to have a vacuum space with a height of ¼ of an infrared wavelength (λ).

4. The thermal image sensor of claim 1, wherein each of the first and second metal layers independently comprises gold (Au), aluminum (Al), chrome (Cr), nickel (Ni), tungsten (W), titanium (Ti), tantalum (Ta), titanium tungsten (TiW), nickel chrome (NiCr), aluminum nitride (AlNₓ), titanium nitride (TiNₓ), titanium aluminum nitride (TiAlₓN_{y}), tantalum nitride (TaNₓ), tungsten silicide (WSiₓ), titanium silicide (TiSiₓ), cobalt silicide (CoSiₓ), or a combination thereof, wherein x and y are independent integers.

5. The thermal image sensor of claim 1, further comprising a cleavage portion formed in the second metal layer so as to cross a central portion of the second metal layer.

6. The thermal image sensor of claim 1, wherein the thermal image sensor and a controller constitute a camera system.

7. A thermal image sensor comprising:
a first metal layer formed on a substrate;
an insulating layer formed on the first metal layer;
a bolometer resistor formed on the insulating layer and comprising a chalcogenide material; and
a second meal layer formed on the bolometer resistor.

8. The thermal image sensor of claim 7, wherein the chalcogenide material comprises an AₐB_{b}S_{1-a-b}, AₐB_{b}Te_{1-a-b} or AₐB_{b}Se_{1-a-b} compound semiconductor,
wherein A is an atom selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni), or a combination thereof,
B is an atom selected from the group consisting of antimony (Sb), bismuth (Bi), arsenic (As), or phosphorus (P), or a combination thereof, and
and having a composition ratio of the chalcogenide material satisfying the formulae 0<a<1 and 0<b<1.

9. The thermal image sensor of claim 7, wherein the insulating layer comprises a silicon oxide (SiO₂) layer, a silicon nitride (Si₃N₄) layer, a titanium oxide (TiO) layer, an aluminum oxide (AlO) layer, or a combination thereof.

10. The thermal image sensor of claim 7, wherein the bolometer resistor is formed to have a thickness corresponding to ¼ of an infrared wavelength (λ).

11. The thermal image sensor of claim 7, further comprising at least one cleavage portion formed in the second metal layer.

12. The thermal image sensor of claim 7, wherein each of the first and second metal layers comprises gold (Au), aluminum (Al), chrome (Cr), nickel (Ni), tungsten (W), titanium (Ti), tantalum (Ta), titanium tungsten (TiW), nickel chrome (NiCr), aluminum nitride (AlNₓ), titanium nitride (TiNₓ), titanium aluminum nitride (TiAlₓN_{y}), tantalum nitride (TaNₓ), tungsten silicide (WSiₓ), titanium silicide (TiSiₓ), cobalt silicide (CoSiₓ), or a combination thereof, wherein x and y are independent integers.

13. The thermal image sensor of claim 7, wherein the thermal image sensor and a controller constitute a camera system.

14. A method of manufacture of a thermal image sensor comprising:
providing a substrate having a read-our integrated circuit (ROIC) thereon;
forming a connector having low thermal conductivity and resistance on the substrate and a supporter for attaching a bolometer on the electrode;
forming a protection layer over the substrate surface and through which the supporter protrudes;
forming a first infrared reflective metal layer comprising gold (Au), aluminum (Al), chromium (Cr), nickel (Ni), titanium (Ti) or an alloy of any two or more thereof on a portion of the substrate for reflecting infrared rays and not in contact with the electrode or supporter;
forming a sacrificial layer over the substrate and the first metal layer such that the supporter protrudes, the sacrificial layer having a thickness of about ¼(λ) over the first metal layer, wherein λ is the wavelength of the infrared rays to be detected by the bolometer;
forming a resistor layer comprising germanium antimony telluride (GST) and a chalcogenide material on a portion of the sacrificial layer and a second metal layer (comprises at least one selected metal from the group consisting of titanium (Ti), nickel (Ni) and platinum (Pt) on the resistor layer and in contact with and supported by the supporter;
removing the sacrificial layer to provide a bolometer electrically connected to the ROIC.

15. The method of manufacture of the thermal image sensor of claim 14, wherein the chalcogenide material comprises a AₐB_{b}S_{1-a-b}, AₐB_{b}Te_{1-a-b} or AₐB_{b}Se_{1-a-b} compound semiconductor,
wherein A is an atom selected from the group consisting of silicon (Si), germanium (Ge), tin (Sn), lead (Pb), aluminum (Al), gallium (Ga), indium (In), copper (Cu), zinc (Zn), silver (Ag), cadmium (Cd), titanium (Ti), vanadium (V), chromium (Cr), manganese (Mn), iron (Fe), cobalt (Co) and nickel (Ni), or a combination thereof,
B is an atom selected from the group consisting of antimony (Sb), bismuth (Bi), arsenic (As), or phosphorus (P), or a combination thereof, and
and having a composition of the chalcogenide material satisfying the formulae 0<a<1 and 0<b<1.
